(19) United States
(12) Patent Application Publication
(10) Pub. No.: US 2009/0103583 A1
(43) Pub. Date: Apr. 23, 2009

(54) Surface emitting laser and manufacturing method thereof

(75) Inventors: Yoshinori Tanaka, Kyoto (JP); Jun Ichihara, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto-fu (JP)

(21) Appl. No.: 12/230,377

(22) Filed: Aug. 28, 2008

(30) Foreign Application Priority Data
Aug. 29, 2007 (JP) 2007-223195
Aug. 29, 2007 (JP) 2007-223197

(51) Int. Cl. H01S 5/18; H01L 21/02

(52) U.S. Cl. 372/45.01; 438/39; 257/E21.002

(57) ABSTRACT

On an n-type GaN buffer layer serving as a common semiconductor layer, mesa regions are formed. The mesa region is formed of a semiconductor stack formed of an n-type GaN layer, an active layer and a p-type GaN layer. A current blocking region is not formed in the mesa region, and the mesa diameter of the mesa region is formed to be not more than 15 μm. The mesa region is formed by selective growth. The mesa region without a surface damage allows sufficient constriction of current and an induced radiation of laser with low current.

### BACKGROUND OF THE INVENTION

1. Field of the Invention

The present invention relates to a so-called vertical cavity surface emitting laser and a method of manufacturing the surface emitting laser.

2. Description of the Related Art

A surface emitting laser which emits light in a perpendicular direction to a semiconductor substrate surface is called a vertical cavity surface emitting laser (VCSEL). In the surface emitting laser, a resonator is formed by stacking semiconductor thin films of, for example, GaAS, InGaAs, or AlGaAs, in a vertical direction to provide a p-n junction, and by forming multilayer reflective mirrors on the top and bottom of the p-n junction. Thereby, the surface emitting laser causes light to vertically reflect multiple times in the resonator to generate coherent light.

Surface emitting lasers are said to be advantageous over edge emitting lasers in terms of low threshold current, high efficiency, and single transverse mode operation. They are increasingly put into practical use as array transmitters for optical communications, and are expected to be used for applications other than the optical communications as well.

One example of the sectional structure of a conventional surface emitting laser is shown in FIG. 10. On an n-type GaAs substrate 22, an n-side multilayer reflective film 23 is formed in which n-type AlGaAs having different Al compositions are alternately stacked. On the n-side multilayer reflective film 23, an active layer 24 having a quantum well structure of an AlGaAs layer and a GaAs layer is stacked.

On the active layer 24, a AlAs current blocking layer 25, a p-side multilayer reflective film 26 in which p-type AlGaAs of different Al compositions are alternately stacked, and a p-type contact layer 27 formed of p-type GaAs are formed as a mesa region 30. A region around the mesa region 30 is filled with a resin 28 having insulation properties, and a p-electrode 29 is provided to cover part of the upper surface of the resin 28 and part of the upper surface of the p-type contact layer 27. An n-electrode 21 is formed on a bottom surface of the GaAs substrate 22. A portion between the n-side multilayer reflective film 23 and the p-side multilayer reflective film 26 described above constitutes a resonator. This resonator causes light to vertically reflect multiple times therein to generate coherent light. Thereby, laser light is emitted through an opening 29A of the p-electrode 29.

Induced radiation of laser requires a high light density, and thus requires a high injected current density. In order to limit the spread of current into a narrow space, a AlAs layer to be formed into the current blocking layer 25 is oxidized from the periphery, so that a narrow current passage region 25b (AlAs portion) remains unoxidized at the center. The peripheral section becomes an aluminum oxide to form a current blocking region 25a, in which no current is caused to flow due to the insulation properties of the aluminum oxide. Thus, current flows only in the current passage region 25b in the center. In this manner, the AlAs current blocking layer 25 has the current passage region 25b which is narrowed by oxidizing the peripheral section, and is also called a current constriction layer.

There are surface emitting lasers in which nitride semiconductors are used as semiconductors so that emission wavelengths of the surface emitting lasers can fall within a blue region. In the surface emitting laser using the nitride semiconductor, a semiconductor layer corresponding to the current blocking layer 25 described above of the mesa region is configured of a AlGaN layer, a AlN layer or the like (for example, see Japanese Patent Application Publication No. 2000-349393 and Japanese Patent Application Publication No. Hei 10-308558).

However, it has been difficult to form an oxidized region in the AlGaN layer or the AlN layer in a manner described above to prepare the current blocking region, since these semiconductors are chemically bonded stably with nitride being a gas element and thus are resistant to oxidation. When the oxidized region is not formed to cause current to flow in the entire mesa region, the current hardly flows to the center of the mesa. This prevents an injected current density that enables induced radiation of laser from being obtained with low driving current. As a conceivable method for solving this problem, the diameter of the mesa region may be reduced.

However, since GaN-based semiconductors including GaN are chemically stable, the mesa region having a small diameter has to be formed by epitaxially growing a stack of the GaN-based semiconductor and then by dry etching the stack. Since a reactive gas, ions, and radicals are used in the dry etching, a surface of the semiconductor layer of the mesa region is damaged even if a mask is used during the dry etching, and this causes leakage current.

In addition, while the mesa diameter has to be made considerably small in order to improve the injected current density to a level at which the induced radiation of laser occurs with low current as described above, there has been a problem that the leakage current due to surface damage of the mesa region increases as the mesa diameter is reduced.

Even when the surface emitting laser is configured of not the nitride semiconductor but of a AlGaAs-based semiconductor or a InGaAlP-based semiconductor, in order to form the mesa region having a small mesa diameter so as to achieve sufficient current constriction as described above, employment of dry etching which enables high-aspect-ratio processing and fine processing with high precision is necessary. However, as in the nitride semiconductor, the surface of the semiconductor layer of the mesa region is damaged during the dry etching to cause leakage current. Moreover, the leakage current increases as the mesa diameter is reduced.

### SUMMARY OF THE INVENTION

The present invention has been made in order to solve the problems described above, and has an object of providing a surface emitting laser, which prevents leakage due to surface damage in a mesa region of the surface emitting laser and in which an injected current density enabling induced radiation of laser with low current is obtained, and a method of manufacturing thereof.

In order to achieve the above object, a first aspect of the present invention provides a surface emitting laser comprising a surface emitting laser element which includes a mesa region including an active layer, and a pair of reflective mirrors provided to sandwich the mesa region, wherein a diameter of the mesa region is formed to be not more than 15 μm.

A second aspect of the present invention provides the surface emitting laser according to the first aspect, wherein the mesa region is formed by selective growth.

A third aspect of the present invention provides the surface emitting laser according to the first aspect, wherein the surface emitting laser element is formed of a nitride semiconductor, and an light emission region of the active layer is configured of a InGaN layer.

A fourth aspect of the present invention provides the surface emitting laser according to the first aspect, wherein the surface emitting laser element is configured of a AlGaAs-based semiconductor or a InGaAlP-based semiconductor.

A fifth aspect of the present invention provides the surface emitting laser according to the first aspect, wherein the pair of reflective mirrors is configured of dielectric multilayer films.

A sixth aspect of the present invention provides the surface emitting laser according to the first aspect, wherein a transparent conductive film is provided between a p-side reflective mirror and the mesa region, the p-side reflective mirror being one, formed on a p-side, of the pair of reflective mirrors.

An seventh aspect of the present invention provides the surface emitting laser according to the first aspect, wherein the mesa region is formed in a hexagonal shape, and a side surface of the mesa region is formed of crystal plane.

An eighth aspect of the present invention provides the surface emitting laser according to the first aspect, wherein aforementioned surface emitting laser elements are formed in an array, and a metal layer is filled in a region between aforementioned mesa regions.

A ninth aspect of the present invention provides the surface emitting laser according to the eighth aspect, wherein the mesa regions of the surface emitting laser elements are formed in an array on an identical semiconductor layer.

A tenth aspect of the present invention provides the surface emitting laser according to the eighth aspect, wherein the mesa regions formed in the array are arranged to form a honeycomb pattern of hexagonal mesas.

An eleventh aspect of the present invention provides the surface emitting laser according to the ninth aspect, wherein an n-side reflective mirror are formed as a continuous reflective mirror on a surface, opposite to a surface in which mesa region are formed, of the identical semiconductor layer, each n-side reflective mirror being one, formed on an n-side, of a pair of reflective mirrors.

A twelfth aspect of the present invention provides a method of manufacturing a surface emitting laser which includes a mesa region including an active layer, and a pair of reflective mirrors provided to sandwich the mesa region and which is formed of a nitride semiconductor, wherein the mesa region is formed by selective growth from a GaN buffer layer formed on a growth substrate, a diameter of the mesa region is formed to be not more than 15 μm, and the reflective mirror is formed after a laser lift off of the growth substrate.

The mesa region is formed in the surface emitting laser element, and an insulating layer including a selective growth mask is formed in the periphery of the mesa region. A current blocking region such as an oxidized region is not provided in the mesa region, and the mesa diameter is formed to be not more than 15 μm. Thus the injected current density can be improved and induced radiation of laser can be performed even with low current. Since the mesa region is prepared by selective growth, leakage current due to a surface damage in the mesa region generated when dry etching is used can be reduced.

The surface emitting laser elements are formed in an array, and the mesa regions are correspondingly formed in an array. Thus, light radiated from each of the mesa regions is combined as laser light outputted from the surface emitting laser, and thereby high-output laser light can be obtained.

### BRIEF DESCRIPTION OF THE DRAWINGS

FIG. 1 is a view showing one example of the sectional structure of a surface emitting laser of the present invention.

FIG. 2 is a view showing one manufacturing step of the surface emitting laser of FIG. 1.

FIG. 3 is a view showing one manufacturing step of the surface emitting laser of FIG. 1.

FIG. 4 is a view showing one manufacturing step of the surface emitting laser of FIG. 1.

FIG. 5 is a view showing one manufacturing step of the surface emitting laser of FIG. 1.

FIG. 6 is a view showing one manufacturing step of the surface emitting laser of FIG. 1.

FIG. 7 is a view showing one example of the shape of a selective growth mask.

FIG. 8 is a view showing a current density distribution in a mesa region when an induced radiation of laser is performed and the size of a mesa diameter of the mesa region is changed.

FIG. 9 is a view showing the relation between the number of DBRs and the reflectivity for each type of material used for a dielectric multilayer reflective film.

FIG. 10 is a view showing the sectional structure of a conventional surface emitting laser.

### DETAILED DESCRIPTION OF THE PREFERRED EMBODIMENTS

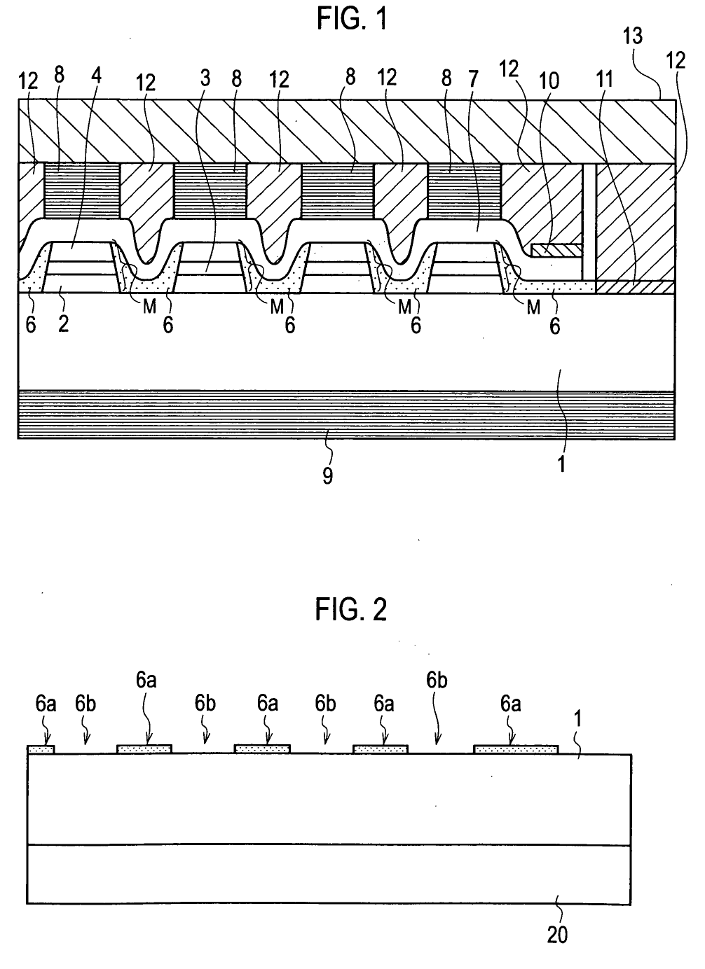

One embodiment of the present invention will be described below with reference to the drawings. FIG. 1 shows the sectional structure of a surface emitting laser of the present invention.

The surface emitting laser is formed of a nitride semiconductor. With an n-type GaN buffer layer 1 as a common semiconductor layer, a plurality of mesa regions M are formed on the GaN buffer layer 1 in one-dimensional array or two-dimensional array. The mesa region M is formed of a semiconductor layer formed of an n-type GaN layer 2, an active layer 3, and a p-type GaN layer 4. Here, the nitride semiconductor refers to an AlGaInN quaternary mixed crystal and is called a III-V nitride semiconductor, which can be represented by AlxGayInzN (x+y+z=1, 0≦x≦1, 0≦y≦1, 0≦z≦1).

An insulating film 6 formed of, for example, SiO₂ (silicon oxide) or SiN (silicon nitride) is formed on the side surfaces of the mesa regions M and the top surface of the GaN buffer layer 1 so as to fill gaps between the mesa regions. As described later, the insulating film 6 includes an insulating film used as a mask for selective growth as a part thereof.

The active layer 3 is an active layer having a quantum well structure, and is structured such that a well layer is sandwiched by barrier layers having larger band gaps than the well layer. The quantum well structure may be in multiple form instead of one, i.e., made into a multi-quantum well (MQW) structure. The active layer 3 may be a light emission region single layer without the quantum well structure.

The active layer 3 is configured by the multi-quantum well structure in which, for example, undoped InGaN well layers and undoped GaN barrier layers are alternately stacked. When the active layer 3 is the light emission region single layer, it is configured of an InGaN single layer.

On the uppermost layer of the mesa region M, i.e., on the p-type GaN layer 4, dielectric multilayer reflective films 8 as p-side reflective mirrors are separately prepared in an array so as to correspond to the mesa region M in an array. On a lower surface of the GaN buffer layer 1, a dielectric multilayer reflective film 9 is continuously formed as an n-side reflective mirror to provide a continuous layer. In this manner, a pair of the reflective mirrors are formed on the outermost positions of a semiconductor stack, which is from the GaN buffer layer 1 to the p-type GaN layer 4, configuring the surface emitting laser.

The portion between the n-side dielectric multilayer reflective film 9 and the p-side dielectric multilayer reflective film 8 constitutes the resonator, and the dielectric multilayer reflective film 9 and the dielectric multilayer reflective film 8 are called DBR mirrors (Bragg reflector mirrors). The resonator corresponds to one surface emitting laser element, and a configuration example of FIG. 1 shows the surface emitting laser in which the surface emitting laser elements are formed in one-dimensional array or two-dimensional array.

In the DBR mirror, reflective surfaces are accumulated at constant intervals so as to satisfy the condition of a Bragg reflection at a certain incidence angle with respect to a particular wavelength. And then, reflective light intensity is strengthened by utilizing the interference of reflective light thus achieving high reflectivity.

For both of the dielectric multilayer reflective films 8 and 9, different materials having a large difference in refractive index are used, such as in a multilayer film of SiO₂ and TiO₂ or a multilayer film of SiO₂ and ZrO₂. Thus, the dielectric multilayer reflective films 8 and 9 are formed by alternately laminating SiO₂ and TiO₂ repeatedly for several cycles or by alternately laminating SiO₂ and ZrO₂ repeatedly for several cycles. Accordingly, the reflectivity can be increased considerably with fewer numbers of DBR pairs than the DBR mirror in which the Al composition ratio of AlGaN is changed.

The dielectric multilayer reflective films 8 and 9 utilize an interference phenomenon between reflective lights from a plurality of boundary surfaces configured of a first reflective film and a second reflective film. Here, the phase difference of light reflecting from the different boundary surfaces is turned 360 degrees so as to strengthen each other and considerably improve the strength of reflective light. For such an operation, the film thickness of the first reflective film is determined as λ/(4×nl) and the film thickness of the second reflective film is determined as λ/(4×n2), where nl is the refractive index of the first reflective film, n2 is the refractive index of the second reflective film, and λ is the wavelength of laser light to be oscillated in the laser resonator.

The GaN buffer layer 1 functions as an n-type contact layer, and a cathode electrode 11 is formed on the GaN buffer layer 1. The p-type GaN layer 4 functions as a p-type contact layer, and a ZnO layer 7 as a transparent conductive film (transparent electrode) is formed on the p-type GaN layer 4.

The ZnO layer 7 as the transparent conductive film (transparent electrode) is continuously formed along upper surfaces of the p-type GaN layer 4 and the insulating film 6, and the ZnO layer 7 formed on each of the upper surfaces of the mesa regions M are continuous. As the transparent conductive film, an ITO layer or the like may be used instead of the ZnO layer. Since ZnO particularly has high resistance, the contact resistance between the ZnO layer 7 and the p-type GaN layer 4 is high. However, as described later, the diameter of the mesa region M is formed to be not more than 15 μm. Thus, the contact area of ZnO decreases and an increase in driving voltage can be prevented.

In the resonator of the surface emitting laser element configured in the portion between the dielectric multilayer reflective films 8 and 9, the optical path therebetween needs to be approximately the same length as the emission wavelength λ of the laser light, and the film thickness of the ZnO layer 7 as the transparent conductive film (transparent electrode) has to be at least λ or less. On the other hand, when the film thickness of the ZnO layer 7 as the transparent conductive film is made thinner than λ/4, it becomes difficult for current to spread in the entire mesa region M, and the current density distribution becomes more uneven. Thus, due to the reasons described above, a film thickness d of the transparent conductive film described above is formed to be within a range of (λ/4)≦d≦λ, where λ is the luminous wavelength of the active layer 3.

An anode electrode (p-electrode) 10 is formed directly on the ZnO layer 7 near the cathode electrode (n-electrode) 11. In this manner, the anode electrode 10 and the cathode electrode 11 are not provided to oppose each other, but are provided on the same mesa region side. The dielectric multilayer reflective films 8 are provided on upper sections of the respective mesa regions M with the ZnO layer 7 therebetween, and metal layer 12 is filled in between the adjacent dielectric multilayer reflective films 8. The metal layer 12 is also filled in between the anode electrode 10 and a supporting substrate 13, and between the cathode electrode 11 and the supporting substrate 13. An upper surface of the metal layer 12 and an upper surface of the dielectric multilayer reflective film 8 are joined with the supporting substrate 13.

The metal layer 12 allows heat generated from the surface emitting laser element to be efficiently radiated externally from the supporting substrate 13. As for the metal layer 12, a metal which particularly exhibits high heat radiation, e.g., Au, Cu, Al, or the like, is used preferably. Ceramic or the like having high heat conductivity is used for the supporting substrate 13, for example. Note that Mg or the like is used as a dopant for making the nitride semiconductor layer into a p-type, and Si or the like is used as a dopant for making the same into an n-type.

A method of manufacturing the surface emitting laser configured as described above will be described below. First, as shown in FIG. 2, the n-type GaN buffer layer 1 is formed on a sapphire substrate 20 being a growth substrate, by epitaxial growth, using a MOCVD method or the like. Then, a selective growth mask 6a is formed on the GaN buffer layer 1. The selective growth mask 6a is used for a selective growth of a nitride semiconductor. Since the growth substrate, such as the sapphire substrate and GaN have different lattice constants, there are dislocations (lattice defects) extending in the vertical direction from the substrates in GaN-based semiconductor layers formed by growth on the growth substrates. As a method of reducing such dislocations, an epitaxial lateral overgrowth (ELO) is well known. The present invention uses the selective growth described above.

By covering the GaN buffer layer 1 with the selective growth mask 6a such as a dielectric mask of SiO₂ or the like, first, growth (selective growth) occurs from an opening 6b of the selective growth mask 6a, and then a growth layer spreads also on the selective growth mask 6a whereby crystal growth occurs in the horizontal direction. Since the crystal growth occurs in the horizontal direction in this manner, when C planes of the sapphire substrate 20 are used as crystal growth planes, the C planes appears on a side surface of the mesa region M and the side surface of the mesa region is formed of the crystal planes.

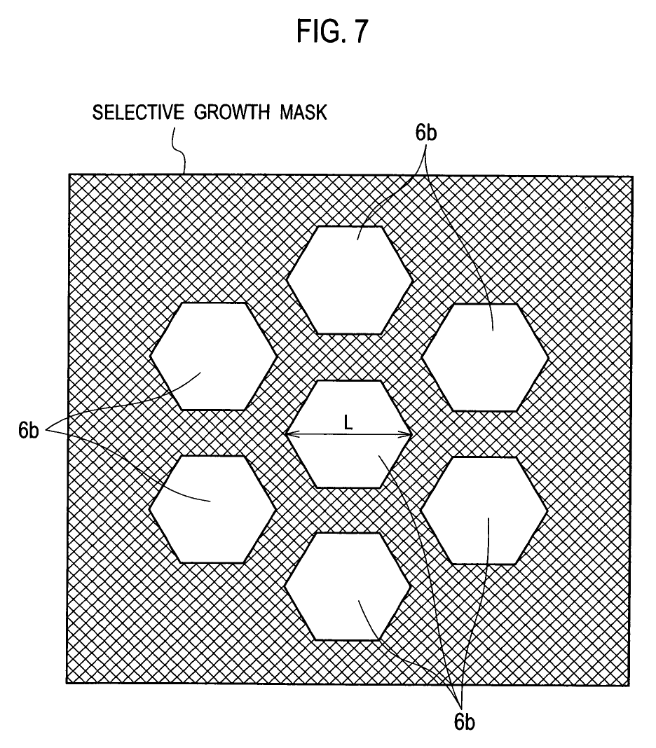

Thus, the opening 6b for the crystal growth is necessary for the selective growth mask 6a, and the shape of the mesa region M formed by the selective growth differs depending on the shape of the opening 6b. A pattern example of the selective growth mask 6a is shown in FIG. 7. In FIG. 7, the shaded region shows the selective growth mask 6a, and white portions show the opening 6b. Like this, the selective growth mask 6a having a honeycomb structure, in which the openings 6b have a regular hexagon shape or a hexagonal shape, is used in this embodiment. This is to improve the integration degree of the mesa region M. Thus, the mesa regions M have approximate regular hexagon or nearly hexagonal shapes when seen from above, and are arranged to form a honeycomb shape. As shown in FIG. 7, when the diameter of the opening 6b is L, the diameter of the mesa region M is also approximately L.

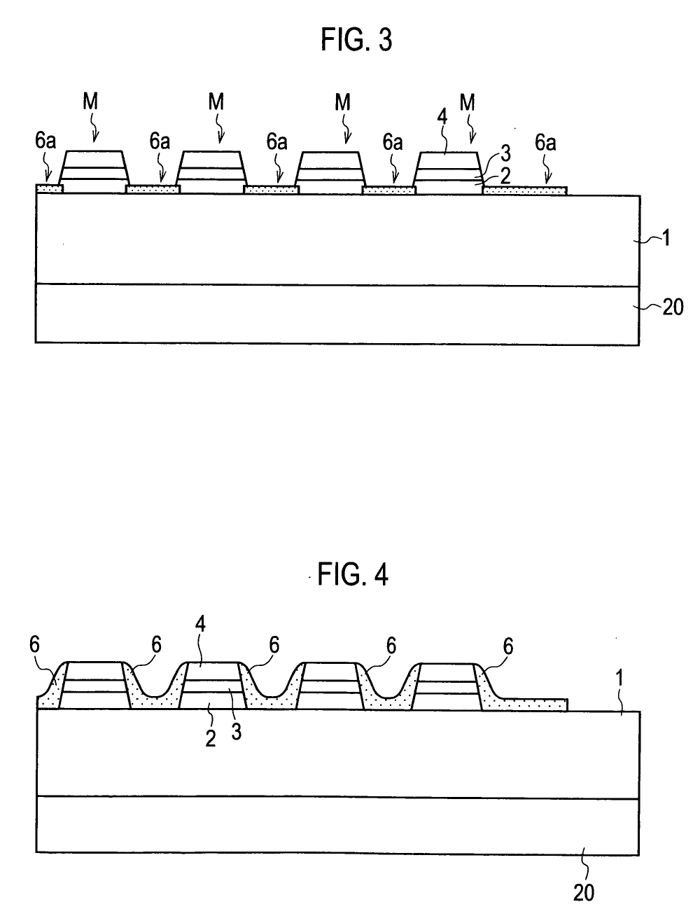

As shown in FIG. 3, the mesa region M is formed by sequentially growing the n-type GaN layer 2, the active layer 3, and the p-type GaN layer 4, in the opening 6b of the selective growth mask 6a. By using the selective growth in this manner, there is no need to prepare the mesa shape by dry etching as in the conventional art. Thus, damage or roughness of the mesa region surface is eliminated, and occurrence of leakage can be prevented.

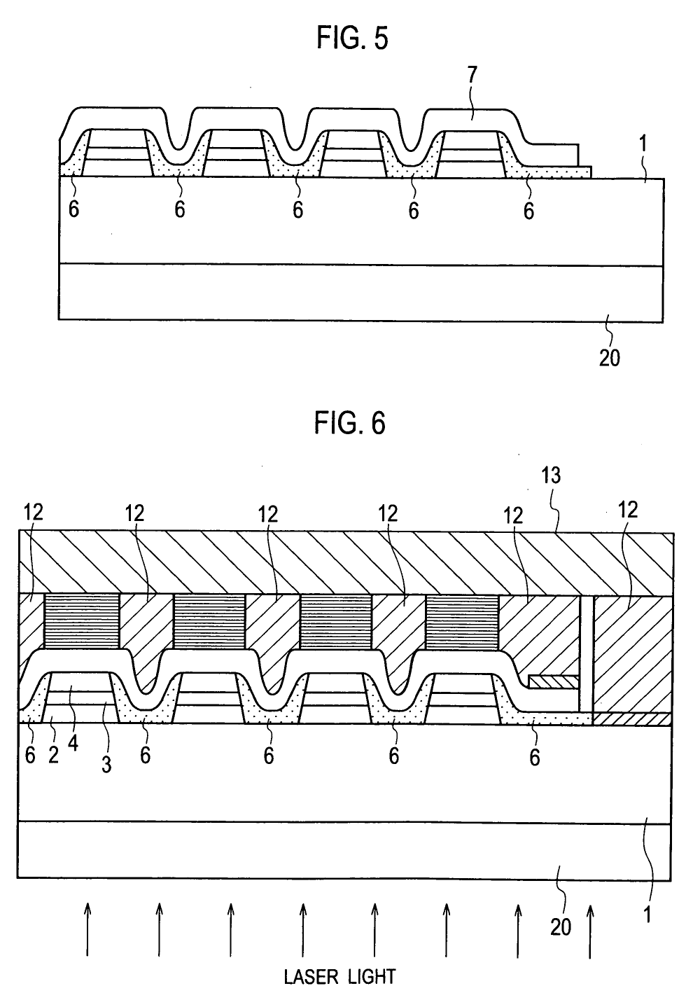

Then, the insulating film 6 such as SiO₂ is stacked along the upper surfaces and side surfaces of the mesa regions M and the surface of the GaN buffer layer 1, by methods such as CVD, plasma CVD, sputtering, spin-on-glass (SOG) method. Portions other than an upper section of the mesa region M, i.e., portion other than an upper section of the p-type GaN layer 4, are covered by a resist. Thereby, etching is performed, removing a part of the insulating film 6 (portion not covered by the resist), and then the resist is removed. The result is shown in the drawing of FIG. 4. Next, as shown in FIG. 5, the ZnO layer 7 (transparent conductive film) is formed in a region in which the insulating film 6 is removed, i.e., along upper surfaces of the p-type GaN layers 4 and upper surfaces of the insulating film 6.

As described above, the selective growth mask 6a is configured of a dielectric mask of SiO₂ or the like, and is a mask with insulation properties. Thus, it can be directly used as a part of the insulating film 6 without being removed. The selective growth mask 6a and the insulating film 6 formed thereon may be of the same material or may be of different materials.

Next, as shown in FIG. 6, the dielectric multilayer reflective film 8 is formed on the ZnO layer 7 by magnetron sputtering or the like while appropriately using the resist or the like. Then, the anode electrode 10 and the cathode electrode 11 are formed, and the metal layers 12 are formed between adjacent dielectric multilayer reflective films 8, on the upper side of the anode electrode 10, and on the upper side of the cathode electrode 11. Then, each of the upper surfaces of the dielectric multilayer reflective films 8 and the metal layers 12 are joined with the supporting substrate 13 being a common substrate. Next, the laser light is applied from the sapphire substrate 20 side, and the sapphire substrate 20 is separated. This method is called a laser lift off, in which excimer laser light of approximately not more than 300 nm is generally applied from the sapphire substrate side at several hundred milli-joules per square centimeter to decompose the GaN buffer layer and separate the sapphire substrate.

After the sapphire substrate 20 is separated by the laser lift off, the dielectric multilayer reflective film 9 is formed on a rear surface of the GaN buffer layer 1 by magnetron sputtering or the like. Thus, the surface emitting laser of FIG. 1 is completed.

Note that, in the method of manufacturing the respective semiconductor layers described above, necessary gas such as reactive gas corresponding to components of the respective semiconductor layers (i.e., triethyl gallium (TEGa) or trimethyl gallium (TMG) as raw material gas of Ga, ammonia (NH₃) as raw material gas of nitride, trimethyl aluminum (TMA) as raw material gas of Al, trymethyl indium (TMIn) as raw material gas of In, and the like), silane (SiH₄) as dopant gas for making an n-type semiconductor, bis-(cyclopentadienyl)-magnesium (CP₂Mg) as dopant gas for making a p-type semiconductor, is supplied together with hydrogen and nitrogen as carrier gases. Thereby respective conductor layers are grown sequentially in a range of 650° C. to 1000° C., whereby desired conductive semiconductor layers can be formed with desired compositions and necessary thicknesses.

When predetermined voltage is applied between the anode electrode (p electrode) 10 and the cathode electrode (n-electrode) 11 in the surface emitting laser, driving current is supplied to each of the surface emitting laser element from the anode electrode 10, flows to the mesa regions M, and is injected into the active layer 3, whereby light is generated. Since current blocking regions such as the oxidized regions are not formed in each of the mesa regions, the entire region of the mesa region becomes the current passage region, whereby the current flows entirely. However, since all of the mesa diameters of the mesa regions M are not more than 15 μm, the current is sufficiently constricted even without the current blocking region, whereby the injected current density which enables induced radiation of laser with low current can be obtained.

Light emitted from the active layer 3 is reflected by the dielectric multilayer reflective film 8 on the p-side and the dielectric multilayer reflective film 9 on the n-side, reciprocates therebetween to generate laser oscillation, and is extracted externally from the dielectric multilayer reflective film 9 as a laser beam. The laser beam is a combination of all light generated in the mesa regions M aligned in an array, whereby a high output laser can be obtained.

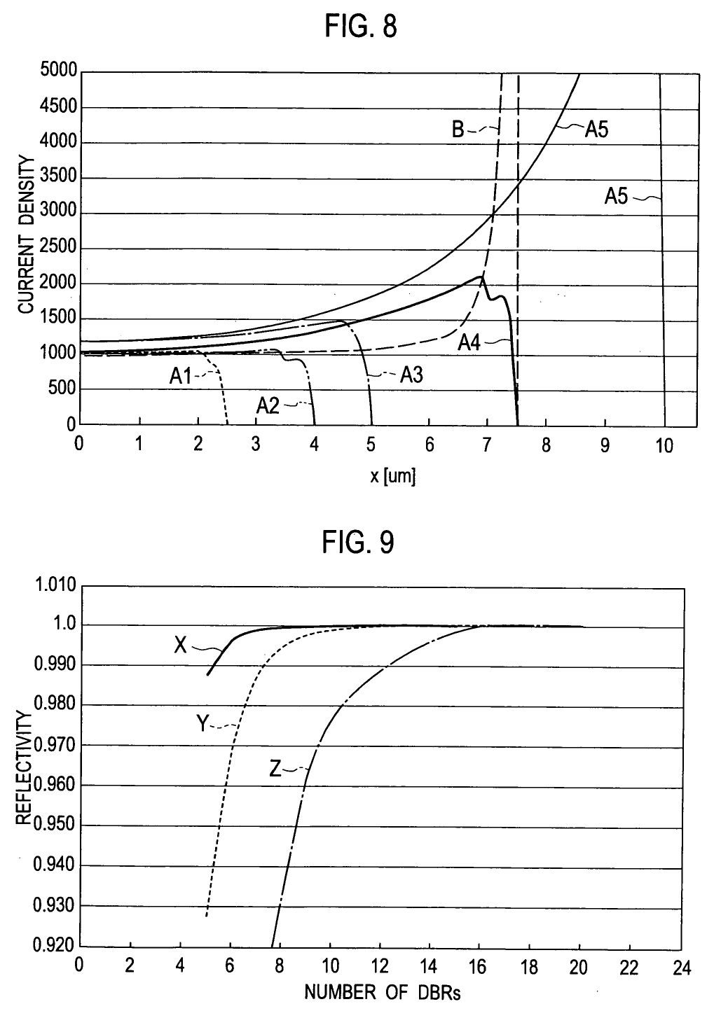

The effect when the mesa diameter is not more than 15 μm as described above will be described below. The surface emitting laser having the configuration of FIG. 1 was prepared. The mesa diameters of the mesa regions M were changed in five stages, and current (laser oscillation current) necessary for achieving a current density, which enables induced radiation of laser, and the current density distribution in the active layer at the time were measured for each one of the mesa region. A graph of corresponding A1 to A5 is shown in FIG. 8. The ordinate of FIG. 8 indicates the current density (A/cm²), and the abscissa indicates the distance (μm) from the center of the mesa diameter. Thus, when the mesa diameter is R, the abscissa shows a value of R/2 which is the radius of the mesa.

The current is caused to flow such that the value of the current density becomes 1000 or greater in the entire mesa region, and the induced radiation of laser was performed. In Al shown by a dotted line in FIG. 8, the mesa diameter was 5 μm, and the current caused to flow in the mesa region was 0.18 mA. In A2 shown by a dashed double-dotted line, the mesa diameter was 8 μm, and the current caused to flow in the mesa region was 0.5 mA. In A3 shown by a dashed-dotted line, the mesa diameter was 10 μm, and the current caused to flow in the mesa region was 2.1 mA. In A4 shown by a solid line, the mesa diameter was 15 μm, and the current caused to flow in the mesa region was 2.7 mA. In A5 shown by a solid line, the mesa diameter was 20 μm, and the current caused to flow in the mesa region was 10.7 mA.

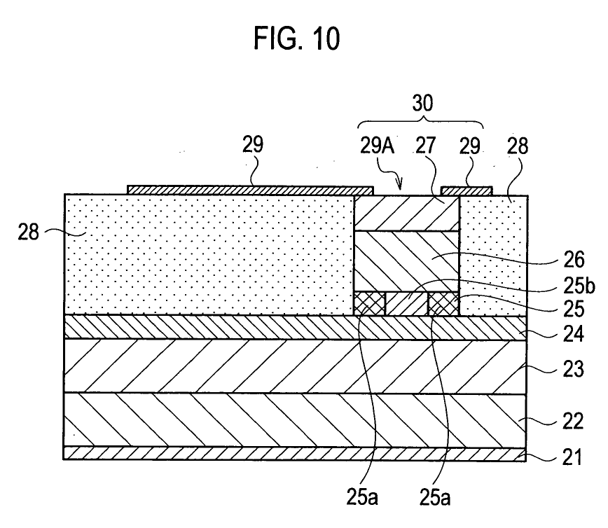

On the other hand, a curve B shown by a dotted line in FIG. 8 represents a surface emitting laser using the conventional structure of FIG. 10. In this laser a peripheral region of the AlAs layer of the current blocking layer 25 was oxidized to prepare the current blocking region 25a and the diameter of the current passage region 25b was set to 15 μm. Current of 3.8 mA was caused to flow so that the value of the current density becomes 1000 or greater in the entire region of the current passage region 25b, and the induced radiation of laser was performed.

As described above, when the mesa diameter is greater than 15 μm the driving current considerably increases. Thus, it can be seen that the mesa diameter has to be not more than 15 μm in order to perform the induced radiation of laser with low current. As can be seen from A1 to A5 and the curve B, the current density is smallest in the center of the mesa region, and the current density increases as the distance increases from the center. Particularly, in the case of A5, the current density considerably increases when the distance from the center is 7 μm to 10 μm in radius, and the difference in current density is extremely large in the peripheral portion and the center portion of the mesa region. When there is too much difference in the current density distribution in this manner, the difference of the laser light strength becomes large between the center and the outside of the beam, which is unfavorable. Regarding this as well, the mesa diameter needs to be made not more than 15 μm. Further, when the current density distribution is to be made uniform to make the laser light strength uniform from the center to the outer edge of the beam, it is preferable that the radius is not more than 5 μm, i.e., the mesa diameter is not more than 10 μm, based on FIG. 8.

FIG. 9 shows the relation between the number of DBRs and the reflectivity for each type of material used for the dielectric multilayer reflective films 8 and 9. The abscissa in FIG. 9 indicates the number of DBRs, i.e., the number of cycles for which pairs of dielectrics of different types are stacked, and the ordinate indicates the reflectivity of light for each number of DBRs. A solid line X shows a dielectric multilayer reflective film in which SiO₂ and TiO₂ are alternately stacked, a dotted line Y shows a dielectric multilayer reflective film in which SiO₂ and ZrO₂ are alternately stacked, and a dashed-dotted line Z shows a dielectric multilayer reflective film in which ZrO₂ and TiO₂ are alternately stacked. As can be seen from the drawing, when the dielectric film is used, the reflectivity is approximately 1 when 15 pairs formed, regardless of any type, and a reflectivity of almost 100% can be obtained with few numbers of layers. Note that, when a multilayer reflective film is formed with a pair of two layers of AlGaN in which the Al compositions are changed, e.g., a combination of Al_{0.1}Ga_{0.9}N and GaN, the reflectivity does not become nearly 100% even with 60 pairs being stacked, whereby the induced radiation of laser is affected.

In the embodiment described above, the surface emitting laser using the nitride semiconductor has been described, but a surface emitting laser using an AlGaAs-based semiconductor or an InGaAlP-based semiconductor as the active layer may also be used. In the case of the surface emitting laser using the AlGaAs-based semiconductor as the active layer, to give an explanation in correspondence with the configuration of FIG. 1, the buffer layer 1 is formed of GaAs, the n-type layer 2 is formed of AlGaAs, the active layer 3 has a multi-quantum well structure in which GaAs well layers and AlGaAs barrier layers are alternately stacked or a multi-quantum well structure in which AlGaAs well layers and AlGaAs barrier layers of different Al compositions are alternately stacked, and the p-type layer 4 is formed of AlGaAs. Other configurations are similar to those of FIG. 1.

In the case of the surface emitting laser using the InGaAlP-based semiconductor as the active layer, to give an explanation in correspondence with the configuration of FIG. 1, the buffer layer 1 is formed of GaAs, the n-type layer 2 is formed of AlGaAs or InGaAlP, the active layer 3 has a multi-quantum well structure in which InGaP well layers and InGaAlP barrier layers are alternately stacked, and the p-type layer 4 is formed of AlGaAs or InGaAlP. Other configurations are similar to those of FIG. 1.

In either cases of the AlGaAs-based and InGaAlP-based surface emitting laser described above, a GaAs substrate or the like is used as the growth substrate. Wet etching is used for separating the GaAs substrate, and as an etching solution a liquid mixture of sulfuric acid and hydrogen peroxide solution, a liquid mixture of hydrochloric acid and hydrogen peroxide solution, or the like is used.

As described above, various embodiments and the like not described herein are obviously included in the present invention. Thus, the technical range of the present invention is defined only by the claims appropriate from the descriptions above.

What is claimed is:

1. A surface emitting laser comprising:
a surface emitting laser element which includes a mesa region including an active layer, and a pair of reflective mirrors provided to sandwich the mesa region, wherein
a diameter of the mesa region is formed to be not more than 15 μm.

2. The surface emitting laser according to claim 1, wherein the mesa region is formed by selective growth.

3. The surface emitting laser according to claim 1, wherein the surface emitting laser element is formed of a nitride semiconductor, and light emission region of the active layer is configured of a InGaN layer.

4. The surface emitting laser according to claim 1, wherein the surface emitting laser element is configured of any one of an AlGaAs-based semiconductor or a InGaAlP-based semiconductor.

5. The surface emitting laser according to claim 1, wherein the pair of reflective mirrors are configured of dielectric multilayer films.

6. The surface emitting laser according to claim 1, wherein a transparent conductive film is provided between a p-side reflective mirror and the mesa region, the p-side reflective mirror being one, formed on a p-side, of the pair of reflective mirrors.

7. The surface emitting laser according to claim 1, wherein the mesa region is formed in a hexagonal shape, and a side surface of the mesa region is formed of a crystal plane.

8. The surface emitting laser according to claim 1, wherein aforementioned surface emitting laser elements are formed in an array, and a metal layer is filled in a region between aforementioned mesa regions.

9. The surface emitting laser according to claim 8, wherein the mesa regions of the surface emitting laser elements are formed in an array on an identical semiconductor layer.

10. The surface emitting laser according to claim 8, wherein the mesa regions formed in the array are arranged to form a honeycomb pattern of hexagonal mesas.

11. The surface emitting laser according to claim 9, wherein n-side reflective mirrors are formed as a continuous reflective mirror on a surface, opposite to a surface in which the mesa regions are formed, of the identical semiconductor layer, each n-side reflective mirror being one, formed on an n-side, of a pair of reflective mirrors.

12. A method of manufacturing a surface emitting laser which includes a mesa region including an active layer, and a pair of reflective mirrors provided to sandwich the mesa region and which is formed of a nitride semiconductor, wherein
the mesa region is formed by selective growth from a GaN buffer layer formed on a growth substrate,
a diameter of the mesa region is formed to be not more than 15 μm, and
the reflective mirror is formed after a laser lift off of the growth substrate.
